(19) United States
(12) Patent Application Publication
(10) Pub. No.: US 2002/0001324 A1
(43) Pub. Date: Jan. 3, 2002

(54) Laser diode module and method of manufacturing the same

(75) Inventors: Jun Miyokawa, Tokyo (JP); Yuichiro Irie, Tokyo (JP); Takeo Shimizu, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD., Tokyo (JP)

(21) Appl. No.: 09/790,603

(22) Filed: Feb. 23, 2001

(30) Foreign Application Priority Data
Feb. 25, 2000 (JP) 2000-048580

(51) Int. Cl. H01S 5/00

(52) U.S. Cl. 372/43

(57) ABSTRACT

A laser diode (LD) device 3 is mounted and fixed on a device mounting stand 2. A lens 5 on a tip side of a lensed fiber 8 fixed on a ferrule 4 and the LD device 3 are opposingly arranged. Centers of the lensed fiber 8 and the LD device 3 are aligned, in which state, the ferrule 4 is held and fixed from both sides of the ferrule 4 by a ferrule fixing components 6 and 7 on a side close to the LD device 3 and a side distant from the LD device 3, respectively. A hold-fixing part 11 of the ferrule 4 on the side distant from the LD device 3 is fixed to the ferrule fixing component 7 using a solder material 10. An inexpensive laser diode module with high long-term reliability can be provided which can be manufactured easily in a short time.

### BACKGROUND OF THE INVENTION

1. Field of the Invention

The present invention relates to a laser diode module mainly used in optical communication and a method of manufacturing the same.

2. Background of the Invention

A laser diode module is formed by optically coupling a laser diode device (optical semiconductor device) that outputs light and an optical fiber that propagates light. FIG. 7a shows an example of a laser diode module in a plane view, and FIG. 7b shows a side view of the laser diode module shown in FIG. 7a. The laser diode shown in FIGS. 7a and 7b include a base 1 made, for example, of metal. On the upper side of the base 1, a device mounting stand 2 is provided. A laser diode device 3 is fixedly mounted on the device mounting stand 2.

A lensed fiber 8 is arranged opposing the laser diode device 3 with spacing. The lensed fiber 8 is an optical fiber on which tip side a lens 5 is formed. As shown in FIGS. 7a and 7b, the lensed fiber 8 is fixed in a ferrule 4 of metal in the state in which the lens 5 on the tip side of the optical fiber protrudes from the ferrule 4. The ferrule 4 is arranged in the state in which the lens 5 of the lensed fiber 8 faces the laser diode device 3, and is held and fixed by ferrule fixing components 6 and 7 of metal at its both sides. The ferrule fixing components 6 and 7 are fixed in the base 1 at fixing parts 22 and 23 by the YAG welding or the like. In addition, the ferrule 4 and the ferrule fixing components 6 and 7 are fixed at hold-fixing parts 9 and 11 by the YAG welding.

In order to receive light emitted from the laser diode device 3 by the optical fiber of the lensed fiber 8 via the lens 5, the lensed fiber 8 is fixed on the base 1 with the ferrule 4 by the ferrule fixing components 6 and 7 as described above in the state in which positioning of an optical axis of the lensed fiber 8 and an optical axis of the laser diode device 3 are in line (centers of the lensed fiber 8 and the laser diode device 3 are aligned).

Further, the tip side of the lens 5 is tapered to a point, and is processed to be optically coupled to the laser diode device 3 easily.

When manufacturing the laser diode module illustrated in FIGS. 7a and 7b, the laser diode device 3 is first mounted and fixed on the device mounting stand 2. In addition, the tip side of the ferrule 4 is mounted on the ferrule fixing component 6, and is fixed at the position of the hold-fixing parts 9 by a YAG laser welding or the like. In doing so, the ferrule 4 is fixed by welding at the ferrule fixing component 6 such that a height position of an optical axis of laser diode device 3 and a height position of an optical axis of the lensed fiber 8 from the upper surface of the base 1 approximately coincide (that is, matching the optical axis of the lensed fiber 8 to the optical axis of the laser diode device 3 in a Y axis direction).

Thereafter, the ferrule fixing component 6 is moved in an X axis direction and a Z axis direction shown in FIGS. 7a and 7b. Thus, the optical axis of the lensed fiber 8 is aligned to the optical axis of the laser diode device 3 in the x axis. At the same time, the lensed fiber 8 is aligned to the laser diode device 3 in the Z axis directions such that a laser beam emitting from the laser diode device 3 can be received by the optical fiber of the lensed fiber 8.

In this way, the lensed fiber 8 is aligned to the laser diode device 3 in all of the X, Y and Z axes directions. Then, the optical fiber fixing component 6 is fixed on the base 1 at the fixing parts 22 by the YAG laser welding or the like.

Further, instead of the procedure described above, i.e. fixing the ferrule fixing component 6 on the base 1 after fixing the ferrule 4 to the ferrule fixing component 6, the ferrule 4 may be fixed to the ferrule fixing component 6 after fixing the ferrule fixing component 6 on the base 1 in advance. In this case, the ferrule fixing component 6 is fixed on the base 1 in advance such that the lensed fiber 8 can be positioned to the laser diode device 3 in the X, Y and Z axes directions.

Then, as shown in FIG. 8, the rear end side of the ferrule 4 is tilted as shown by an arrow A of FIG. 8 using the hold-fixing parts 9 as a fulcrum with a aligning jig 19. Thus, by slightly moving the tip side of the lens 5 of the lensed fiber 8 in the Y axis direction, the optical axis of the laser diode device 3 and the optical axis of the lensed fiber 8 is fine-tuned in the Y axis direction and positioned accurately. Then, as shown in FIGS. 7a and 7b in that state, the rear end side of the ferrule 4 is welded and fixed to the ferrule fixing component 7 at hold-fixing parts 11. In this way, the optical axis of the laser diode element 3 and the optical axis of the lensed fiber 8 can be positioned accurately. That is, the centers of the laser diode device 3 and the lensed fiber 8 can be aligned with high accuracy.

FIG. 10 shows another example of the conventional laser diode module as a perspective view. In FIG. 10, same reference numerals are affixed to the parts which have the same names as those in the laser diode module shown in FIGS. 7a and 7b. Characteristic to the laser diode module shown in FIG. 10 is that the ferrule fixing component 7 for fixing the part of the ferrule 4 that is distant from the laser diode device 3 has a peculiar shape as shown in FIG. 10. The other configurations of the laser diode module of FIG. 10 are approximately the same as those in the laser diode module shown in FIGS. 7a and 7b. Here, repeated descriptions of the common parts are omitted.

The above-mentioned peculiar shaped ferrule fixing component 7 is a component that is can be elastically and plastically deformed in a state in which the ferrule fixing component 7 holds the ferrule 4. When manufacturing the laser diode module shown in FIG. 10, the tip side of the ferrule 4 is first held and fixed by the ferrule fixing component 6 in the manner similar to that for the laser diode module shown in FIGS. 7a and 7b. Then, the laser diode device 3 and the lensed fiber 8 are positioned, and the ferrule fixing component 6 is fixed on the base 1.

After fixing the ferrule fixing component 6 on the base 1, center aligning (positioning in the Y axis directions) operation is performed using the hold-fixing parts 9 as a fulcrum. Thereafter, as shown in FIG. 10, the ferrule fixing component 7 is arranged and fixed on the base 1. Then, the ferrule 4 for which the center aligning operation has been finished is fixed to the ferrule fixing component 7 at the hold-fixing points 11 by the YAG laser welding.

In fixing at the hold-fixing pars 11, the ferrule 4 causes positional deviation, thereby deviating the optical axis of the laser diode device 3 and the optical axis of the lensed fiber 8 in the Y axis directions. In order to correct this deviation, a force in the X and Y directions is applied to the ferrule fixing component 7 as shown by arrows B of FIG. 11 to plastically deform the ferrule fixing component 7. Thus, by tiltingly displaces the ferrule 4 with the hold-fixing parts 9 as a fulcrum, the centers of the optical axis of the laser diode device 3 and the optical axis of the lensed fiber 8 are finally aligned.

Incidentally, the laser diode module shown in FIGS. 7a and 7b or the laser diode module shown in FIG. 10 uses the lensed fiber 8. On the other hand, there is also a laser diode module that does not utilize the lensed driver 8 (i.e., a laser diode module formed by optically coupling in advance a general optical fiber that does not have the lens 5 formed on its tip side and the laser diode device 3 to make them module). In such a laser diode module, in order to optically couple the laser diode device 3 and an optical fiber, one or more micro-optic lenses such as spherical lense or non-spherical lense are provided between the laser diode device 3 and the optical fiber.

Compared with the center aligning of the laser diode device 3 and the optical fiber 8 in such a laser diode module, it is regarded as inevitable to align the centers of the lensed fiber 8 and the laser diode device 3 with extremely high accuracy in the laser diode module using the above-mentioned lensed fiber 8. This is the reason, since the tip side of the lens 5 of the lensed fiber 8 is processed as tapered to a point, an optical coupling tolerance to positional deviation of an optical fiber is very narrow.

Due to the reasons mentioned above, it is important to fix the ferrule 4 to the ferrule fixing components 6 and 7 for positioning and fixing the lensed fiber 8 in a laser diode module using the lensed fiber 8. Particularly, it is important to fix the ferrule 4 to the ferrule fixing component 7. As described above, when manufacturing a laser diode module, the part of the ferrule 4 close to the laser diode device 3 (the hold-fixing parts 9) is first held and fixed to the ferrule fixing component 6. Thereafter, the centers of the lensed fiber 8 and the laser diode device 3 are aligned by tilting the ferrule 4 using the hold-fixing parts 9 as a fulcrum. Then, the ferrule 4 is fixed to the ferrule fixing component 7. In this way, since the fixing of the ferrule 4 to the ferrule fixing component 7 (fixing of the part of the ferrule 4 that is distant from the laser diode device 3) is the final fixing operation of the ferrule 4, it is important as described above.

However, as described above, when fixing the part of the ferrule 4 that is on the side distant from the laser diode device 3, weld fixing such as the YAG laser welding is conventionally performed. In the fixing method by the YAG laser welding, for example, as shown in FIG. 9, the hold-fixing parts 11 is instantaneously heated locally by irradiating a laser beam. Thus, metals in the ferrule and the ferrule fixing component 7 are caused to melt, and then instantaneously solidify to form an alloy. Therefore, the fixing method by the YAG laser welding is a method of connecting and fixing the ferrule 4 and the ferrule fixing component 7 that are made of metal.

When fixing the ferrule 4 and the ferrule fixing component 7 by such a welding, the ferrule 4 falls into the ferrule fixing component 7 and causes positional deviation by the above-mentioned welding of metals as shown by an arrow D in FIG. 9. In addition, when the above-mentioned melt metal solidifies, the ferrule 4 and the ferrule fixing component 7 pull each other and deform as shown by arrows C in FIG. 9. Due to such positional deviation and deformation of the ferrule 4, there is a problem in that the optical axis of the ferrule 4(i.e., the optical axis of the lensed fiber 8 fixed to the ferrule 4) whose center has been aligned to the center of the laser diode device 3 very carefully deviates.

Therefore, in a laser diode module shown in FIG. 10, the part of the ferrule 4 on the side distant from the laser diode device 3 is fixed using the peculiar shaped ferrule fixing component 7 shown in FIG. 10. However, in this configuration, the ferrule fixing component 7 is required that the centers of the laser diode device 3 and the lensed fiber 8 can be easily aligned, and the aligned center state can be maintained for a long period. In order to meet these requirements, the ferrule fixing component 7 takes a complicated form such as shown in FIGS. 10 and 11. Thus, costs of the ferrule fixing component 7 is increased. There is a problem in that this makes the laser diode module of FIG. 10 using the ferrule fixing component 7 expensive as well.

In addition, as shown in FIG. 11, when the centers of the lensed fiber 8 and the laser diode device 3 are aligned by transforming the ferrule fixing component 7, it is necessary to perform the above-mentioned center alignment operation anticipating return due to elastic deformation until plastic deformation of the ferrule fixing component 7 is attained. Thus, there is a problem in that the center alignment operation takes time and manufacturing of a laser diode module is not easy.

Moreover, when the ferrule fixing component 7 is transformed, according to a ratio of a distance from the hold-fixing parts 9 to the ferrule fixing component 7 (b in FIG. 10) to a distance from the tip end of the lens 5 to the hold-fixing pars 9 (a in FIG. 10), the ferrule fixing component 7 must be transformed. For example, if a:b is 1:10, the ferrule fixing component 7 must be transformed by an amount ten times an amount of slight movement of the tip end of the lens 5. Besides, as described before, since the ferrule fixing component 7 must be excessively transformed anticipating return due to elastic deformation, the amount of transformation of the ferrule fixing component 7 inevitably becomes large.

In the laser diode module shown in FIG. 10, before fixing the ferrule 4 to the ferrule fixing component 7, the ferrule 4 is tilted using the hold-fixing pars 9 as a fulcrum for center alignment as hereinbefore described. Then, after fixing the ferrule 4 to the ferrule fixing component 7, the ferrule 4 must be tilted largely again using the hold-fixing parts 9 as fulcrum for center realignment as described above. Thus, distortion due to torsion stress or the like tends to occur at a welded point of the hold-fixing parts 9. Due to such distortion, a crack or the like tends to occur at a welded point of the hold-fixing parts 9 while using the laser diode module. Therefore, there also is a problem in that characteristics of the laser diode module degrades and reliability is decreased as a result of occurrence of such a crack.

### OBJECTS AND SUMMARY OF THE INVENTION

The present invention has been devised in order to solve the above-mentioned conventional problems, and it is an object of the present invention to provide an inexpensive and highly reliable laser diode module in which positional deviation between an optical axis of a lensed fiber and an optical axis of a laser diode device can be controlled when fixing a part of a ferrule on a distant side from the laser diode device to a fixing component, and which can be easily manufactured in a short time.

In order to attain the above-mentioned object, the present has the following aspects as means for solving the afore-mentioned problems. That is, a first aspect of the present invention is a laser diode module that has a configuration in which a laser diode device is mounted and fixed onto a device mounting stand fixed on a base; a lensed fiber on which a lens is formed on a tip side of an optical fiber opposing the laser diode device is arranged with the tip side on which the lens is formed oriented to the laser diode device side; the lensed fiber is fixed to a ferrule by protruding from the tip side on which the lens is formed from a tip end of the ferrule; and the lensed fiber receives a laser beam emitting from the laser diode device in the optical fiber via the lens, wherein the ferrule is held and fixed by a fixing component from on both of a side close to the laser diode device and a side distant from the laser diode device in a state in which centers of the lensed fiber and the laser diode device are aligned, and a hold-fixing part on the side distant from the laser diode device is fixed to the fixing component using a fixing agent for joining the fixing component without melting it.

As hereinbefore mentioned, in a laser diode module using a lensed fiber, fixing a ferrule to a ferrule fixing component is important. Particularly, fixing a part of the ferrule on a side distant from a laser diode device to the fixing component is important. When the part of the ferrule on the side distant from the laser diode device is fixed to the fixing component by welding in a conventionally manner, positional deviation of the ferrule with respect to the fixing component occurs due to melting of a welded part of the fixing component and the ferrule at the time of welding as described before. In addition, the ferrule is deformed by a tensile force acting on the ferrule at the time of solidification of the melted metal. Due to the positional deviation the ferrule with respect to the fixing component and the deformation of the ferrule described above, a situation arises in which the optical axis of the laser diode device and the optical axis of the lensed fiber are positionally deviated.

On the other hand, in the present invention, a part of a ferrule on a side distant from a laser diode device is fixed to a fixing component using a fixing agent. The fixing agent can fix the ferrule and the fixing component without melting the fixing component or the ferrule. Thus, when fixing the ferrule and the fixing component, positional deviation of the ferrule due to melting of a fixed part of the ferrule or the fixing component or deformation of the ferrule due to solidification of the welded part can be controlled. Therefore, positional deviation between the optical axis of the laser diode device and the optical axis of the lensed fiber can be prevented.

In addition, in the present invention, it is not necessary to largely displace a rear end side of the ferrule for center realignment after fixing the rear end side of the ferrule to the fixing component as is required for the laser diode module shown in FIG. 10. Thus, occurrence of distortion in a hold-fixing part of the ferrule on the side close to the laser diode device due to torsion stress can be controlled. Also what can be prevented is generation of a crack at, for example, the welded part of the hold-fixing part while using the laser diode module caused by distortion applied to the hold-fixing part of the ferrule on the side close to the laser diode. Therefore, the problem in that characteristics of the laser diode module degrade and reliability decreases due to the crack can be prevented.

Moreover, in the present invention, an expensive fixing component with a complicated shape as shown in FIG. 10 is not required. Thus, costs of the laser diode module can be reduced that much.

Therefore, it becomes possible to provide an inexpensive and highly reliable laser diode module that can be easily manufactured.

### BRIEF DESCRIPTION OF THE DRAWINGS

These and other objects and advantages of the present invention will be more apparent and more readily appreciated from the following detailed description of the exemplary embodiments of the invention taken in conjunction with the accompanying drawings, in which:

FIG. 1a is a schematic plane view illustrating a main part configuration of a first embodiment of a laser diode module in accordance with the present invention;

FIG. 1b is a schematic side view illustrating the main part configuration of the laser diode module shown in FIG. 1a;

FIG. 2 is a perspective view illustrating an example of a ferrule fixing component 7 forming the laser diode module of the first embodiment;

FIG. 3a is a perspective view illustrating another example of the ferrule fixing component 7;

FIG. 3b is a perspective view illustrating another example of the ferrule fixing component 7;

FIG. 4A is a perspective view illustrating another example of the ferrule fixing component 7;

FIG. 4b is a perspective view illustrating an example of a ferrule fixing component 7 forming a laser diode module of a second embodiment;

FIG. 5a is a schematic plane view illustrating the laser diode module of the second embodiment;

FIG. 5b is a schematic side view of the laser diode module shown in FIG. 5a;

FIG. 6a is a schematic plane view showing an example of another hold-fixing method of a part of a ferrule on a side close to a laser diode device;

FIG. 6b is a schematic side view of the part of the ferrule on the side close to the laser diode device shown in FIG. 6a;

FIG. 7a is a schematic plane view of an example of a main part configuration of a conventional laser diode module;

FIG. 7b is a schematic side view of the main part configuration of the laser diode module shown in FIG. 7a;

FIG. 8 is a schematic side view illustrating a center aligning method with the part of the ferrule on the side close to the laser diode device as a fulcrum in the conventional laser diode module;

FIG. 9 is a view illustrating, using a cross section cut by the line A-A′ shown in FIG. 7B, a problem at the time when a part of the ferrule on a side distant from the laser diode device in the conventional laser diode module is fixed by the YAG laser welding;

FIG. 10 is a perspective view illustrating another example of the conventional laser diode module; and

FIG. 11 is a view illustrating a final center aligning operation in the laser diode module shown in FIG. 10.

### DETAILED DESCRIPTION OF THE PREFERRED EMBODIMENT

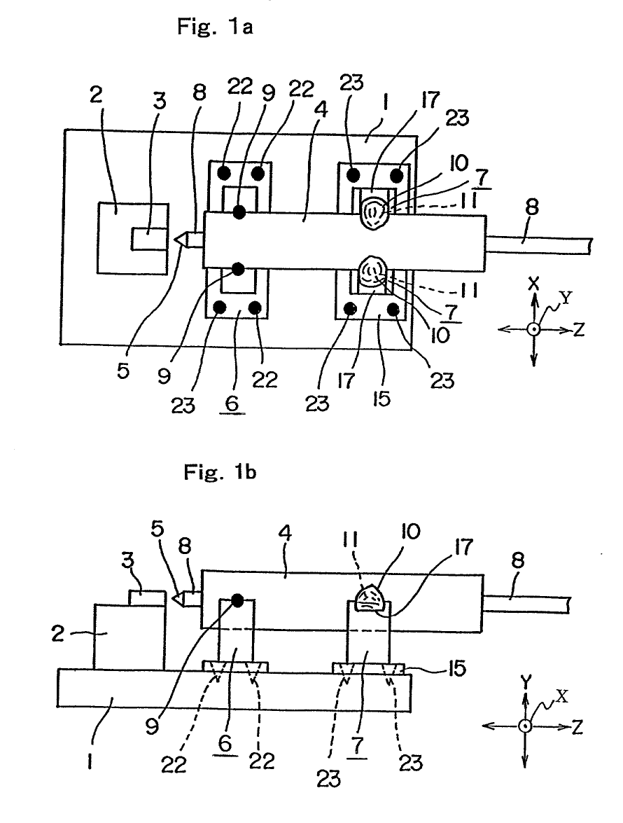

Embodiments of the present invention will be hereinafter described with reference to drawings. In the following descriptions of the embodiments, like reference numerals used throughout the figures of the present invention refer to like or corresponding parts of a conventional example, and repeated descriptions on common parts are omitted. FIG. 1a shows a plane view of a first embodiment of a laser diode module in accordance with the present invention, and FIG. 1b shows a side view of the laser diode module shown in FIG. 1A.

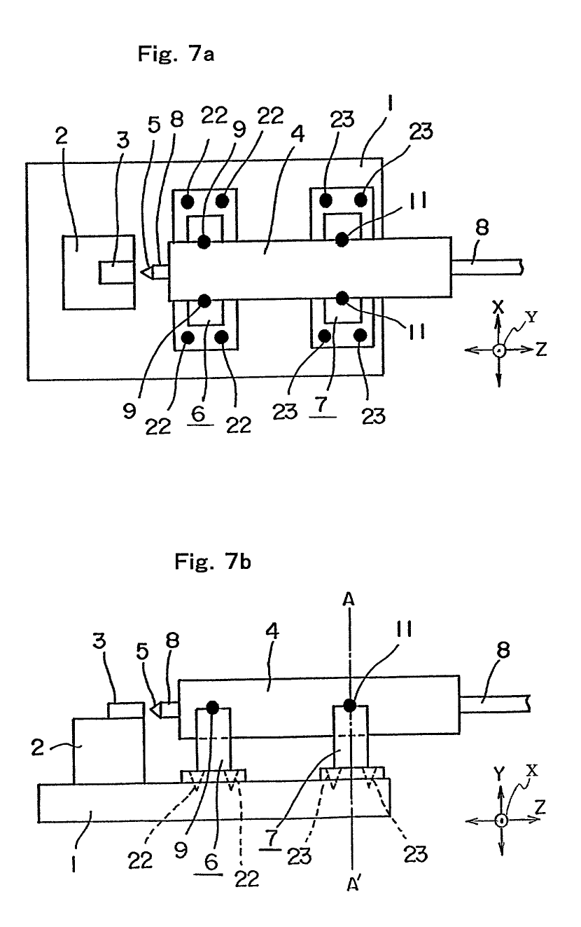

As shown in FIGS. 1a and 1b, the laser diode module of the first embodiment is configured approximately same as the conventional laser diode module shown in FIGS. 7a and 7b. Characteristic to the laser diode module of the first embodiment which differentiate it from the laser diode module shown in FIGS. 7a and 7b is that the rear end side of the ferrule 4 and the ferrule fixing component 7 are fixed on the hold-fixing parts 11 using solder material 10 as a fixing agent. The solder material (fixing agent) 10 joints the ferrule fixing component 7 and the ferrule 4 without melting the ferrule 4 and the ferrule fixing component 7.

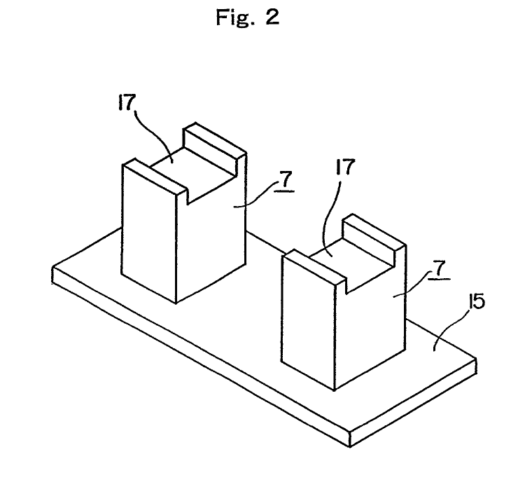

In this first embodiment, the ferrule fixing component 7 has a form shown in FIG. 2. As shown in FIG. 2, two ferrule fixing components 7 are fixed on one fixing plate 15. Solder material drawing recesses 17 are formed on the surface sides of the ferrule fixing components 7 as shown in FIG. 2. The solder material drawing recesses 17 are parts on which the solder material 10 is mounted. In addition, the solder material drawing recesses 17 are provided with a function to prevent the solder material 10 from flowing out in a longitudinal direction of the ferrule 4.

In the first embodiment, an eutectic solder material such as shown in Table 2 is used as the solder material 10 considering temperature control and convenience. Further, a non-eutectic solder material such as shown in Table 1 may be used as the solder materials 10. In Tables 1 and 2, for example, the one with a composition shown as 95Sn - 5Sb means an Sn mixing amount of 95/100 pst.wt. and an Sb mixing amount of 5/100 pst.wt., and similarly a numerical value in each composition indicates a mixing amount in percentage.

TABLE 1

| Composition | Melting Point |
|---|---|
| 50In - 50Pb | 210° C.-178° C. |
| 90Sn - 10Pb | 213° C.-183° C. |
| 95Sn - 5Ag | 240° C.-221° C. |
| 95Sn - 5Sb | 240° C.-232° C. |

TABLE 2

| Composition | Melting Point |
|---|---|
| 62.5Sn - 36.1Pb - 1.4Ag | 179° C. |
| 63Sn - 37Pb | 183° C. |
| 91Sn - 9Zn | 199° C. |
| 96.5Sn - 3.5Ag | 221° C. |
| 82.6Cd - 17.4Zn | 266° C. |
| 80Au - 20Sn | 280° C. |
| 97.5Pb - 2.5Ag | 303° C. |
| 97.5Pb - 1.5Ag - 1Sn | 309° C. |
| 88Au - 12Ge | 356° C. |
| 96.76Au - 3.24Si | 365° C. |

It is desired of the laser diode module that a fixed part of the ferrule 4 and the ferrule fixing components 7 do not degrade when a temperature cycle test is conducted at temperatures, for example, of −30° C. to 80° C. Considering this point, it is preferred that 80Au-20Sn among the eutectic solders shown in Table 2 is used as the solder materials 10. This is because the solder material of the above mentioned 80Au-20Sn has a particularly high tensile strength at a high temperature (85° C.). In addition, if a non-eutectic solder is used as the solder materials 10, 95Sn-5Sb having an excellent creep strength is preferred among the non-eutectic solders shown in Table 1.

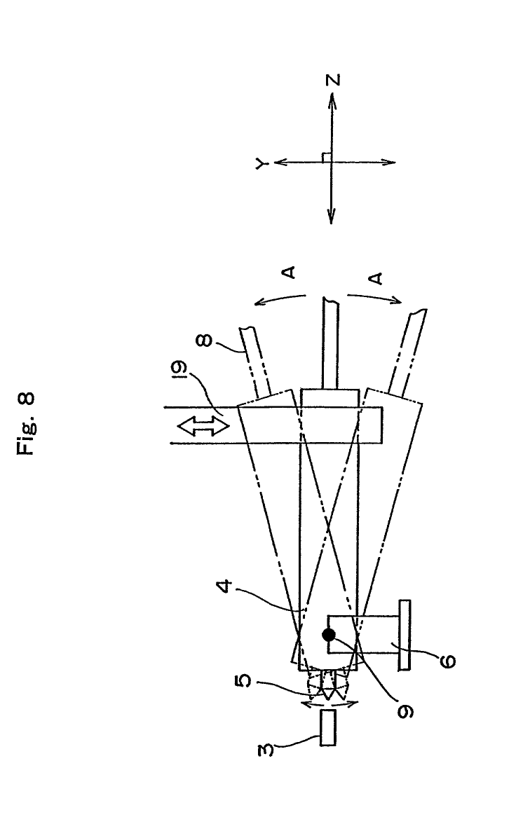

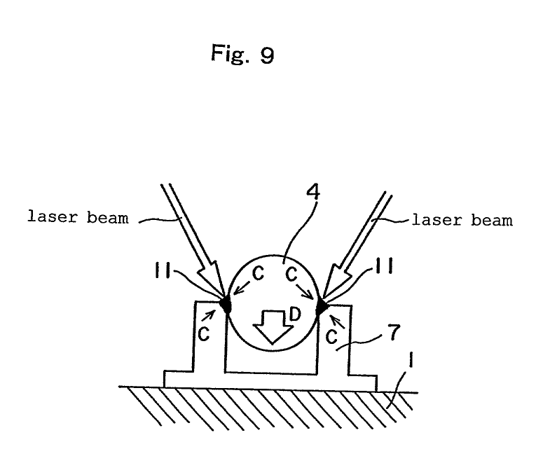

The first embodiment is configured as described above. In the first embodiment, the laser diode module is manufactured substantially in the same manner as the laser diode module shown in FIGS. 7a and 7b. However, in the first embodiment, when the rear end side of the ferrule 4 is fixed, a fixing operation is performed as described below. For example, the above-mentioned solder materials 10 are mounted on the solder material drawing recesses 17 of the ferrule fixing components 7 by a center aligning operation of the laser diode device 3 and the lensed fiber 8 shown in FIG. 8 in a state in which the optical axis of the laser diode device 3 and the optical axis of the lensed fiber 8 coincide. Then, the solder material 10 is melted and are joined to the ferrule 4 and the ferrule fixing components 7. Thereafter, the solder material 10 is cooled to solidify. Thus, the ferrule 4 is fixed to the ferrule fixing components 7 by the solder material 10.

As described hereinbefore, the solder material 10 can fix the ferrule 4 and the ferrule fixing components 7 without melting the ferrule 4 or the ferrule fixing components 7. Thus, occurrence of a problem due to weld-fixing of the ferrule 4 and the ferrule fixing components 7 can be prevented. That is, when the ferrule 4 and the ferrule fixing components 7 are welded and fixed, the ferrule 4 is positionally deviated with respect to the ferrule fixing components 7 by melting of welded parts of the ferrule 4 and the ferrule fixing components 7. In addition, the ferrule 4 is deformed by a tensile force due to solidification of the welded parts. As a result of the positional deviation and the deformation of the ferrule 4, a problem in that the optical axis of the laser diode device 3 and the optical axis of the lensed fiber 8 deviate occurs. On the other hand, in the first embodiment, since the solder material 10 is fixed without welding and fixing the ferrule 4 and the ferrule fixing components 7, the above-mentioned problem due to welding and fixing can be prevented from occuring.

According to the first embodiment, as described above, positional deviation of the ferrule 4 with respect to the ferrule fixing components 7 and deformation of the ferrule 4 can be controlled when the ferrule 4 is fixed to the ferrule fixing components 7. Thus, the ferrule 4 can be fixed to the ferrule fixing components 7 in a state in which the center of the lensed fiber 8 is aligned with the center of the laser diode device 3 with high accuracy.

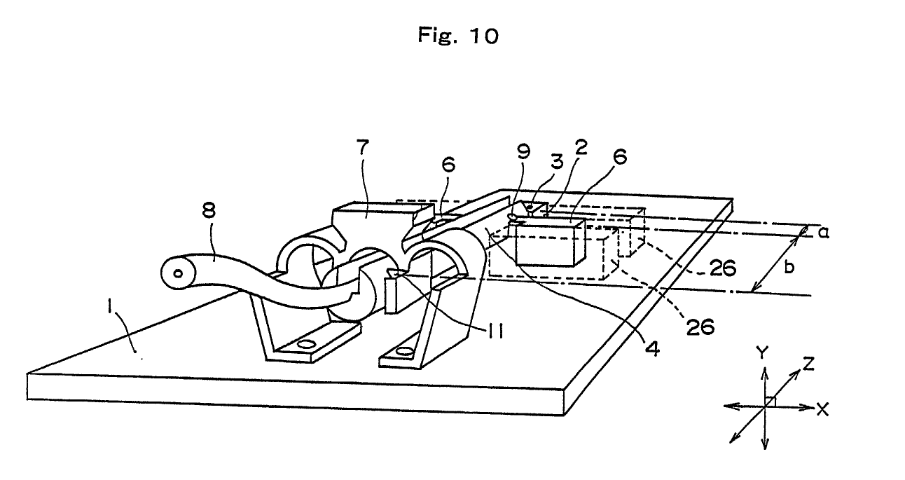

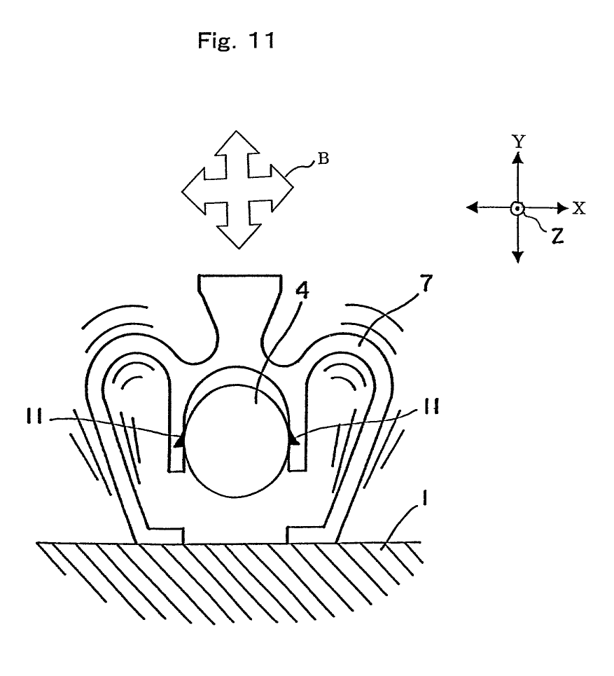

In addition, in the first embodiment, the center alignment operation of the laser diode device 3 and the lensed fiber 8 needs not to be performed again after fixing the ferrule 4 to the ferrule fixing components 7 as the laser diode module shown in FIG. 10 is required. Thus, it is not necessary to considerably move the end part of the ferrule on the side distant from the laser diode device 3. Thus, occurrence of distortion by torsion stress or the like in hold-fixing parts 9 of the ferrule 4 on the side close to the laser diode device 3 can be controlled.

Therefore, a situation can be prevented in which a crack or the like in the hold-fixing parts 9 is generated due to the distortion applied to the hold-fixing parts 9 of the ferrule 4 on the side close to the laser diode device 3 while the laser diode module is used. Thus, a problem in that characteristics of the laser diode module degrade and reliability decreases due to a crack or the like can also be prevented.

Moreover, according to the first embodiment, it is not necessary to use an expensive component with a complicated form as shown in FIG. 10 as the ferrule fixing components 7. Thus, the laser diode module can be formed using the ferrule fixing components 7 with a simple configuration as shown in FIG. 2. Therefore, costs of the laser diode module can be reduced that much.

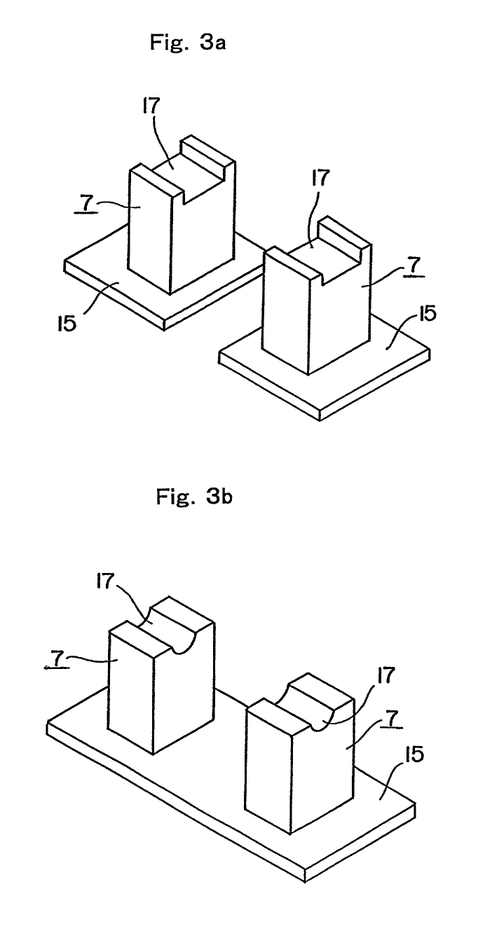

Further, a form of the ferrule fixing components 7 to be used in the laser diode module is not specifically limited, and can be properly set. For example, as shown in FIG. 3a, the fixing plate 15 may be separated. In this case, since the fixing plate 15 is separated, it is easy to adjust the spacing between the ferrule fixing components 7 and the ferrule 4, and to also adjust appropriate conditions for solder fixing. In addition, as shown in FIG. 3b, the solder material drawing recesses 17 formed on the ferrule fixing components 7 may be in a U shape.

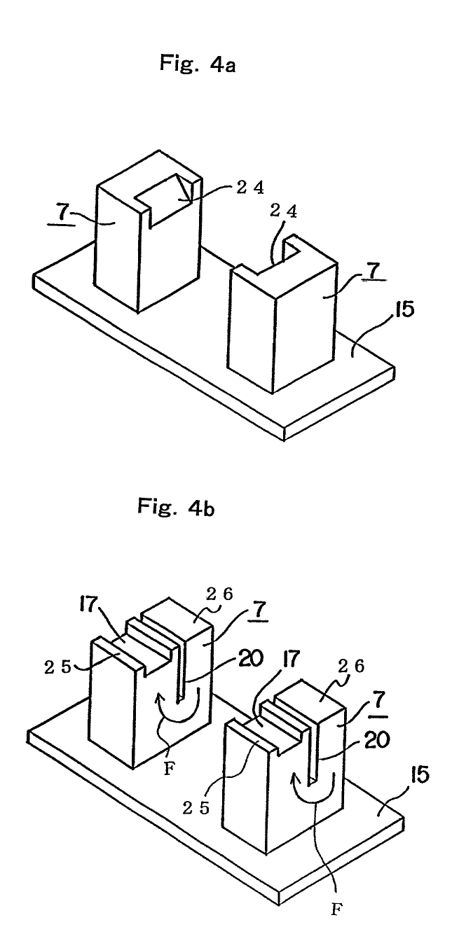

In addition, as shown in FIG. 4a, slopes 24 may be provided in the ferrule fixing components 7 such that the solder materials 10 can be drawn to the side of the ferrule 4 easily.

A second embodiment of the present invention will be hereinafter described. In description of the second embodiment, like reference numerals used throughout the figures concerning the second embodiment refer to like or corresponding parts of the first embodiment, and repeated descriptions on common parts are omitted.

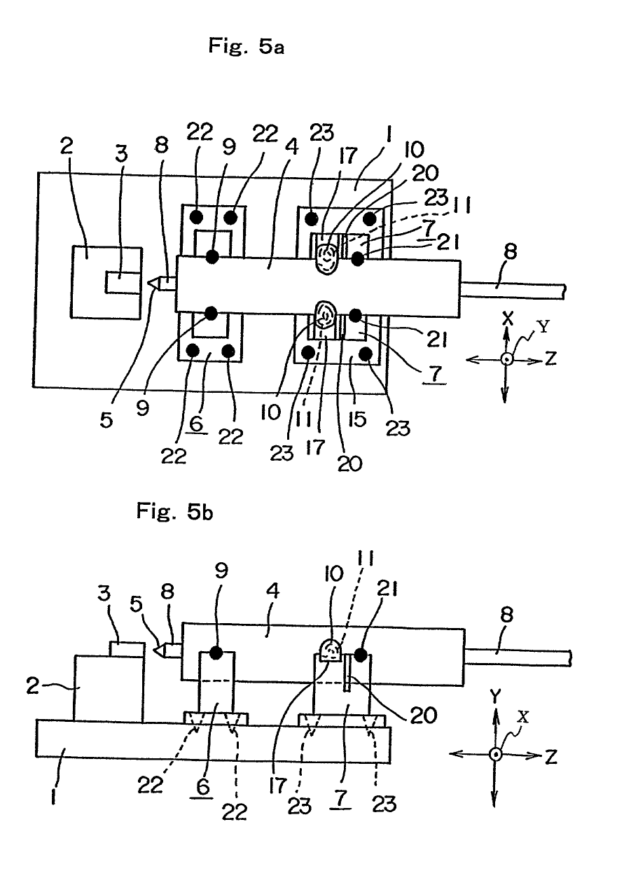

In a laser diode module of the second embodiment, long-term improvement of reliability is attempted. That is, as shown in FIGS. 5a and 5b, the ferrule fixing components 7 (components for fixing the part of the ferrule 4 on the side distant from the laser diode device 3) and the ferrule 4 are fixed by both of the solder materials 10 and welding 21 (e.g., the YAG laser welding). The other configurations are substantially the same as those of the first embodiment.

In the second embodiment, the ferrule fixing components 7 are provided with a form shown in a perspective view of FIG. 4b. That is, the ferrule fixing components 7 have solder fixing parts 25 and weld-fixing parts 26, and separation gaps 20 are formed between the solder fixing parts 25 and the weld-fixing parts 26. As shown in FIG. 4b, the solder fixing parts 25 are parts on which the ferrule 4 is fixed via the solder material 10. The solder material drawing recesses 17 indicated in the first embodiment are formed in the solder fixing parts 25. In the second embodiment, the separation gaps 20 are configured by forming a groove deeper than the solder material drawing recesses 17 between the solder fixing parts 25 and the weld-fixing parts 26.

In the second embodiment, the fixing operation of the part of the ferrule 4 on the side distant from the laser diode device 3 and the ferrule fixing components 7 is performed as described below. For example, in the same manner as in the first embodiment, the part of the ferrule 4 on the side distant from the laser diode device 3 is fixed to the solder fixing parts 25 of the ferrule fixing components 7 by the solder material 10. Thereafter, the ferrule 4 is fixed to the weld-fixing parts 26 of the ferrule fixing components 7 by the YAG laser welding. The ferrule 4 and the ferrule fixing components 7 are fixed with such processes.

In fixing the ferrule 4 and the ferrule fixing components 7, a temperature of the weld-fixing parts 26 rises extremely high due to heating at the time of the welding. When the heat of the weld-fixing parts 26 is directly transferred to the solder fixing parts 25, a situation arises in which the previously mounted solder material 10 are melted by the heat. If the solder material 10 are melted, the ferrule 4 tends to deviate, thus positional deviation between the optical axis of the laser diode device 3 and the optical axis of the lensed fiber 8 occurs as in the conventional case due to positional deviation and deformation of the ferrule 4 that are caused by the welding of the weld-fixing parts 26.

On the other hand, in the second embodiment, as described above, the separation gaps 20 are provided between the solder fixing parts 25 and the weld-fixing parts 26. Thus, the heat of the weld-fixing parts 26 is transferred to the solder fixing parts 25 bypassing the separation gaps 20 as shown by arrows F in FIG. 4b. In this way, the high temperature heat due to the welding is not directly transferred to the solder materials 10, and a situation can be avoided in which the solder materials 10 are melted at the time of welding the weld-fixing parts 26.

In addition, by providing the separation gaps 20, even if the solder material 10 should bulge out of the solder material drawing recesses 17, the solder material 10 flow down in the separation gaps (grooves) 20. Thus, the solder materials 10 bulging out of the solder material drawing recesses 17 do not stick to the weld-fixing parts 26.

The weld-fixing parts 26 are parts that are fixed to the ferrule 4 by welding such as the YAG laser welding. If impurities such as the solder material 10 stick to the weld-fixing parts 26, fixing of the ferrule 4 and the ferrule fixing components 7 by the YAG laser welding cannot be performed accurately. As described above, the second embodiment has a configuration in which the solder material 10 is certainly prevented from sticking to the weld-fixing parts 26 by the separation gaps 20. Thus, the fixing of the ferrule 4 and the ferrule fixing components 7 by the YAG laser welding can be accurately performed.

Further, the fixing by the solder material 10 takes longer time than the fixing by the YAG welding. Thus, when fixing is performed using the solder material 10 with a high melting point, an ambient temperature of a fixing part tends to rise due to the solder material 10. Therefore, if a high ambient temperature is not allowed, the ferrule 4 is fixed to the ferrule fixing components 7 using the solder material 10 with relatively low melting point temperature.

However, the solder material 10 with a low melting point temperature have poor characteristics of the afore-mentioned temperature cycle test compared with the solder material 10 with high melting point temperature. Thus, decrease of long term reliability of the laser diode module due to a change in a temperature environment of use is concerned. Therefore, when the solder materials 10 with a low melting point temperature are used, it is preferable to fix the ferrule 4 to the ferrule fixing components 7 on the solder fixing parts 25 using the solder materials 10 as shown in this second embodiment. Thereafter, the ferrule 4 is fixed to the ferrule fixing components 7 on the weld-fixing parts 26 by the YAG welding. By such a double fixing, decrease of reliability due to a change in a temperature environment of use can be controlled, which is very effective.

However, the solder material drawing recesses 17 of the solder fixing parts 25 are not limited to the form shown in FIG. 4b, and maybe, for example, in a U shape. In addition, instead of the solder material drawing recesses 17, the slopes 24 shown in FIG. 4a may be provided in the solder fixing parts 25.

Further, the present invention is not limited to each of the above-mentioned embodiments, and various embodiments can be adopted. For example, although the solder material drawing recesses 17 are provided in the solder fixing parts of the ferrule fixing components 7 in each of the above-mentioned embodiments, the solder material drawing recesses 17 are not necessarily provided in the ferrule fixing components 7. However, when the ferrule fixing components 7 are formed with the solder material drawing recesses 17, the solder material 10 can be prevented from flowing out in the longitudinal direction of the ferrule 4. Thus, the ferrule 4 and the ferrule fixing components 7 can be fixed more certainly as designed.

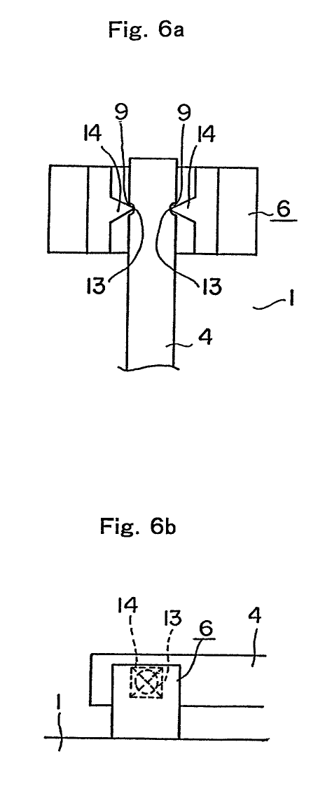

In addition, in each of the above-mentioned embodiments, the end part side of the ferrule 4 on the side close to the laser diode device 3 is held by the ferrule fixing components 6, and welded and fixed to form the hold-fixing parts 9. However, the part of the ferrule 4 on the side close to the laser diode device 3 can be held and fixed by the ferrule fixing components 6, for example, as illustrated in FIGS. 6a and 6b (a side view of FIG. 6a). That is, recesses 13 are formed on the side face of the ferrule 4 as shown in FIGS. 6a and 6b (the side view of FIG. 6A). In addition, protruding parts 14 are protrudingly formed on the ferrule fixing components 6 toward the recesses 13, which correspond to the recesses 13. The protruding parts 14 are tapered to a point. The ferrule fixing components 6 hold and fix the ferrule 4 by causing the protruding parts 14 to abut internal wall surfaces of the recesses 13 of the ferrule 4.

With such a configuration, the end part of the ferrule 4 on the side close to the laser diode device 3 can be held and fixed in a point contact state. Thus, when the centers of the laser diode device 3 and the lensed fiber 8 are aligned with the hold-fixing parts 9 as a fulcrum, the laser diode device 3 and the lensed fiber 8 can be freely tilted with the tip ends of the protruding parts 14 as a fulcrum. Therefore, the center alignment operation with the hold-fixing parts 9 as a fulcrum can be performed much easier. In addition, application of excessive force to the hold-fixing parts 9 of the ferrule 4 can be avoided. Moreover, unlike the case in which the ferrule 4 is welded and fixed to the ferrule fixing component 6, generation of a crack in the hold-fixing parts 9 can be certainly avoided. Thus, reliability of the laser diode module can be further increased.

Moreover, the ferrule fixing component 6 may be formed by a staking member that can give staking force in the ferrule 4, and the ferrule 4 may be fixed by the staking force given by the staking member. In this way, in the present invention, the hold-fixing method of the part of the ferrule 4 on the side close to the laser diode device 3 is not specifically limited and is properly set, and any method may be used to hold and fix the part.

Moreover, in each of the above-mentioned embodiments, when the part of the ferrule 4 on the side distant from the laser diode device 3 is fixed to the ferrule fixing components 7, the solder material 10 is used as a fixing agent. However, the fixing agent is not always limited to the solder materials 10. The fixing agent may be any fixing agent as long as it can join the ferrule fixing components 7 without melting it when the ferrule 4 is fixed to the ferrule fixing components 7.

Thus, it is seen that a laser diode module and method of manufacturing the same are provided. One skilled in the art will appreciate that the present invention can be practiced by other than the preferred embodiments which are presented for the purposes of illustration and not of limitation, and the present invention is limited only by the claims which follow.

What is claimed is:

1. A laser diode module; comprising:
a base;
a device mounting stand fixed on said base;
a laser diode device mounted and fixed on said device mounting stand;
a lensed fiber on which a lens is formed on a tip side of an optical fiber and which receives a laser beam emitting from said laser diode device in said optical fiber via said lens;
a ferrule for fixing said lensed fiber by causing a part on which said lens is formed on said tip side of said optical fiber to protrude;
a fixing component for holding and fixing said tip side of said ferrule;
a fixing component for holding and fixing a rear end side of said ferrule; and
a fixing agent for fixing a hold-fixing part of said rear end side of said ferrule.

2. A laser diode module according to claim 1, wherein said fixing agent is a solder material.

3. A laser diode module according to claim 2, wherein said fixing component for fixing said rear end side of said ferrule is joined with said ferrule by welding and said solder material.

4. A laser diode module according to claim 3, wherein said fixing component for fixing said rear end side of said ferrule is provided with both a solder fixing part and a weld-fixing part, and a separation gap is formed between said solder fixing part and said weld-fixing part.

5. A laser diode module according to claim 2, wherein a surface side of said fixing component for fixing said rear end side of said ferrule is provided with a recess for drawing said solder material.

6. A laser diode module according to claim 5, wherein said solder drawing recess is a recess in a U shape.

7. A laser diode module according to claim 5, wherein a slope for drawing said solder material to the side of said ferrule is formed on said solder drawing recess.

8. A laser diode module according to claim 1, wherein said fixing component for holding and fixing said tip side of said ferrule and said ferrule are joined and fixed by welding.

9. A laser diode module according to claim 1, wherein a protrusions protruding toward said ferrule from both holding faces of said ferrule are formed on said fixing component for holding and fixing said tip side of said ferrule;
a recess is formed at parts corresponding to said protrusions in said ferrule; and
said protrusions of said fixing component abut internal wall surface of said recess of said ferrule and said fixing component holds and fixes said tip side of said ferrule.

10. A laser diode module according to claim 2, wherein said solder material is an eutectic solder.

11. A method of manufacturing a laser diode module, comprising:
a step S1 of mounting a laser diode device on a device mounting stand and mounting said device mounting stand on a base;
a step S2 of fixing a lensed fiber on a ferrule;
a step S3 of aligning centers of said lensed fiber and said laser diode device;
a step S4 of fixing a tip side of said ferrule on said base via a first fixing component;
a step S5 of fixing a second fixing component on said base; and
a step S6 of fixing a rear end side of said ferrule to said second fixing component with a fixing agent.

12. A method of manufacturing a laser diode module according to claim 11, further comprising a step of fixing said rear end side of said ferrule to said second fixing component by welding after the step S6.

13. A method of manufacturing a laser diode module according to claim 11, wherein said tip side of said ferrule and said first fixing component are welded and fixed in the step S4.

14. A method of manufacturing a laser diode module according to claim 11, wherein the centers of said laser diode device and said lensed fiber are aligned by tilting said ferrule with a welded part of said tip side of said ferrule and said first fixing component as a fulcrum after the step S4, and thereafter the steps S5 and S6 are performed.
